(19) United States
(12) Patent Application Publication
(10) Pub. No.: US 2026/0284822 A1
(43) Pub. Date: Sep. 24, 2026

(54) POLISHING HEAD AND POLISHING APPARATUS

(71) Applicant: EBARA CORPORATION, Tokyo (JP)

(72) Inventors: Keisuke UCHIYAMA, Tokyo (JP); Satoru YAMAMOTO, Tokyo (JP)

(21) Appl. No.: 19/140,947

(22) PCT Filed: Nov. 14, 2023
(86) PCT No.: PCT/JP2023/040939

§ 371 Date: Jun. 4, 2026

(30) Foreign Application Priority Data
Dec. 26, 2022 (JP) 2022-208452

(51) Int. Cl. B24B 21/08; B24B 37/11; B24B 41/06

(52) U.S. Cl. CPC B24B 21/08; B24B 37/11; B24B 41/06

(57) ABSTRACT

The present invention relates to a polishing head for pressing a polishing tape against a substrate, such as a wafer. Further, the present invention relates to a polishing apparatus for polishing the substrate with such a polishing head. The polishing head (10) for polishing the substrate (W) includes: a pressing member (12) configured to press the polishing tape (2) against the substrate (W); and an actuator (15) coupled to the pressing member (12) and configured to apply a pressing force to the pressing member (12). The pressing member (12) has multiple protrusions (50), and the multiple protrusions (50) are arranged along a longitudinal direction of the pressing member (12) and are arranged along an advancing direction (Z) of the polishing tape (2).

### TECHNICAL FIELD

The present invention relates to a polishing head for pressing a polishing tape against a substrate, such as a wafer. Further, the present invention relates to a polishing apparatus for polishing the substrate with such a polishing head.

### BACKGROUND ART

Devices, such as memory circuits, logic circuits, and image sensors (e.g., CMOS sensors), are becoming more highly integrated these days. In a process of forming such devices, foreign matter, such as fine particles or dust, may adhere to the devices. Foreign matter adhering to a device can cause a short-circuit between interconnects or can cause a circuit defect. Therefore, in order to enhance a reliability of the device, it is necessary to clean a wafer on which the device is formed to remove the foreign matter on the wafer.

Foreign matter, such as fine particles or dust, as described above may also adhere to a back surface (or a non-device surface) of the wafer. If such foreign matter adheres to the back surface of the wafer, the wafer can separate from a stage reference plane of an exposure apparatus, so that a surface of the wafer can incline with respect to the stage reference plane. As a result, patterning shift or focal distance shift can occur. In order to prevent such problems, it is necessary to remove the foreign matter adhering to the back surface of the wafer.

Thus, as shown in FIGS. 15 and 16, a polishing apparatus for polishing the back surface of the wafer with a polishing tape has been used. FIG. 15 is a top view of a conventional polishing apparatus, and FIG. 16 is a side view of the conventional polishing apparatus shown in FIG. 15. The polishing apparatus rotates a wafer W by rotating multiple rollers 500 themselves while a periphery of the wafer W is held by these rollers 500. A polishing tape 502 is disposed on a back side of the wafer W. The polishing tape 502 advances in a direction indicated by arrow Z in FIGS. 15 and 16.

Multiple polishing heads 505 are aligned in a diameter direction of the wafer W. These polishing heads 505 are configured to press the polishing tape 502 against the back surface of the wafer W, thereby polishing the back surface of the wafer W. More specifically, as shown in FIG. 16, each polishing head 505 has a pressing member 512 configured to press the polishing tape 502 against the back surface of the wafer W. Each polishing head 505 is configured to polish the back surface of the wafer W with the polishing tape 502 by pushing the polishing tape 502 up toward the wafer W with the pressing member 512. The polishing tape 502 is pressed against the back surface of the wafer W can therefore remove foreign matter from the back surface of the wafer W.

### CITATION LIST

### Patent Literature

Patent document 1: Japanese laid-open patent publication No. 2021-122895

### SUMMARY OF INVENTION

### Technical Problem

During polishing of the wafer W, when the polishing tape 502 advances in the direction indicated by the arrow Z in FIGS. 15 and 16, friction occurs between the pressing member 512 of the polishing head 505 and a back surface of the polishing tape 502. This friction may cause the polishing tape 502 to pull a comer of the pressing member 512 at an upstream side in the advancing direction Z of the polishing tape 502, and as a result, a pressing force of the polishing head 505 against the polishing tape 502 may be biased. Specifically, as shown in FIG. 17, a pressing force Fa at the upstream side in the advancing direction Z of the polishing tape 502 is larger than a pressing force Fb at a downstream side in the advancing direction Z of the polishing tape 502. Polishing rates of polishing regions polished by the multiple polishing heads 505 may be higher at the upstream side in the advancing direction Z of the polishing tape 502. As a result, the polishing tape 502 may not be able to polish the wafer W uniformly.

Therefore, the present invention provides a polishing head capable of uniformly pressing a polishing tape against a substrate, such as a wafer, with a pressing member. The present invention further provides a polishing apparatus including such a polishing head.

### Solution to Problem

In an embodiment, there is provided a polishing head for polishing a substrate, comprising: a pressing member configured to press a polishing tape against a substrate; and an actuator coupled to the pressing member and configured to apply a pressing force to the pressing member, wherein the pressing member has multiple protrusions, and the multiple protrusions are arranged along a longitudinal direction of the pressing member and are arranged along an advancing direction of the polishing tape.

In an embodiment, the multiple protrusions are arranged obliquely with respect to the advancing direction of the polishing tape.

In an embodiment, the multiple protrusions are arranged at equal intervals.

In an embodiment, the pressing member includes a first pressing member and a second pressing member arranged symmetrically with respect to the advancing direction of the polishing tape, the multiple protrusions include multiple protrusions of the first pressing member and multiple protrusions of the second pressing member, and the multiple protrusions of the first pressing member and the multiple protrusions of the second pressing member are arranged at different positions in longitudinal directions of the first pressing member and the second pressing member.

In an embodiment, there is provided a polishing apparatus comprising: a substrate holder configured to support the substrate; and the above-mentioned polishing head for polishing the substrate.

### Advantageous Effects of Invention

According to the present invention, the pressing member of the polishing head has the multiple protrusions arranged along the longitudinal direction of the pressing member and are arranged along the advancing direction of the polishing tape, so that a pressing force of the polishing head against the polishing tape is distributed to the multiple protrusions. Therefore, the pressing force of the pressing member against the polishing tape is not biased, and as a result, the polishing tape can be pressed against the substrate uniformly.

### BRIEF DESCRIPTION OF DRAWINGS

FIG. 1 is a perspective view showing an embodiment of a polishing head configured to press a polishing tape, which is an example of a polishing tool, against a surface of a wafer, which is an example of a substrate, to polish the wafer;

FIG. 2 is a cross-sectional view of the polishing head shown in FIG. 1;

FIG. 3 is a top view showing an embodiment of a pressing member;

FIG. 4 is a cross-sectional view of the pressing member shown in FIG. 3;

FIG. 5A is a diagram showing an example of a polishing profile when a polishing head including a pressing member that does not have multiple protrusions is used;

FIG. 5B is a diagram showing an example of a polishing profile when the polishing head including the pressing member that has multiple protrusions is used;

FIG. 6 is a top view showing another example of multiple strip members;

FIG. 7 is a top view showing still another example of the multiple strip members;

FIG. 8 is a top view showing still another example of the multiple strip members;

FIG. 9 is a top view showing another embodiment of the pressing member;

FIG. 10 is a side view of the pressing member shown in FIG. 9;

FIG. 11 is a top view showing still another embodiment of the pressing member;

FIG. 12 is a top view showing an embodiment of a polishing head including two pressing members;

FIG. 13 is a side view showing an embodiment of a polishing apparatus;

FIG. 14 is a top view of the polishing apparatus shown in FIG. 13;

FIG. 15 is a top view of a conventional polishing apparatus;

FIG. 16 is a side view of the conventional polishing apparatus shown in FIG. 15; and

FIG. 17 is a diagram illustrating bias that occurs in a pressing force of a polishing head against a polishing tape.

### DESCRIPTION OF EMBODIMENTS

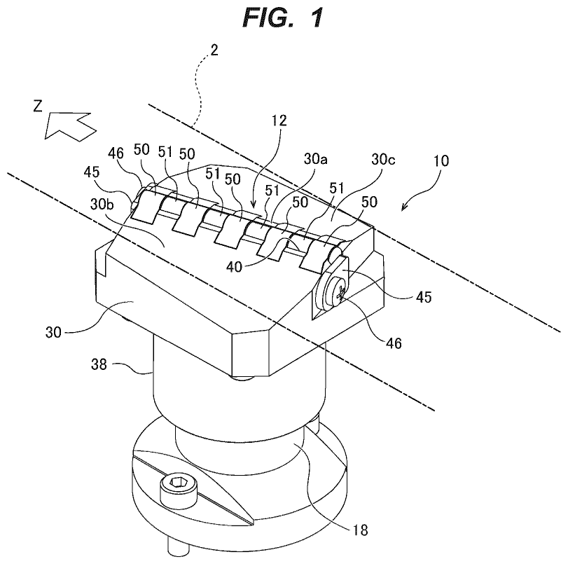

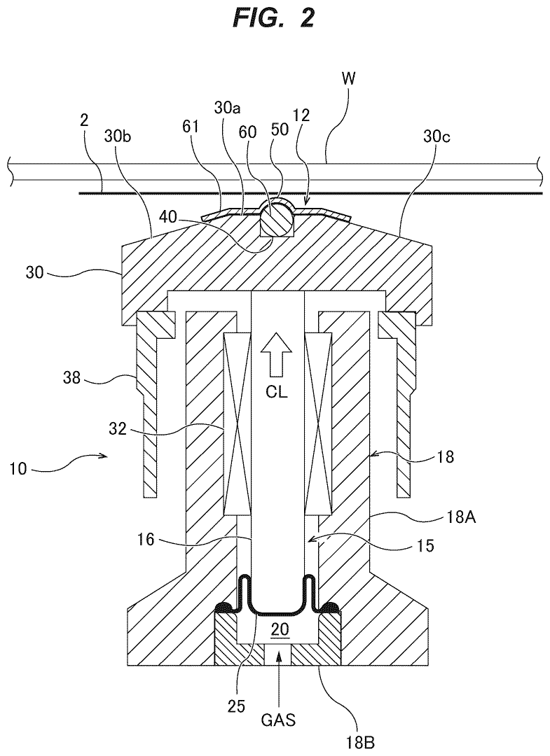

Hereinafter, embodiments of the present invention will be described with reference to the drawings. FIG. 1 is a perspective view showing an embodiment of a polishing head 10 configured to press a polishing tape 2, which is an example of a polishing tool, against a surface of a wafer W, which is an example of a substrate, to polish the wafer W. FIG. 2 is a cross-sectional view of the polishing head 10 shown in FIG. 1. The polishing head 10 of this embodiment is arranged below the wafer W and the polishing tape 2, and is arranged so as to press the polishing tape 2 against a back surface of the wafer W from a back side of the polishing tape 2.

The polishing head 10 includes a pressing member 12 configured to press the polishing tape 2 against the wafer W, an actuator 15 configured to move the pressing member 12 in a predetermined pressing direction indicated by an arrow CL in FIG. 2 to apply a pressing force to the pressing member 12, and a housing 18 in which the actuator 15 is disposed. The actuator 15 includes a movable shaft 16 coupled to the pressing member 12, and a partition membrane (diaphragm) 25 forming a pressure chamber 20 between an end of the movable shaft 16 and the housing 18. The movable shaft 16 and the partition membrane 25 are disposed in the housing 18.

The polishing head 10 further includes a pressing-member holder 30 configured to hold at least a part of the pressing member 12. The pressing-member holder 30 is coupled to the movable shaft 16 and can move together with the movable shaft 16. In this embodiment, the pressing-member holder 30 is fixed to the movable shaft 16, and an angle of the pressing-member holder 30 relative to the movable shaft 16 is fixed. The pressing-member holder 30 has a fitting groove 40 formed in a pressing surface 30a of the pressing-member holder 30, and at least a part of the pressing member 12 is fitted in the fitting groove 40. The pressing-member holder 30 has slope surfaces 30b and 30c inclined downwardly toward outside from both sides of the pressing surface 30a.

As shown in FIG. 2, the movable shaft 16 is configured to be movable in its axial direction in the housing 18. The movable shaft 16 can elevate the pressing member 12 in the pressing direction indicated by the arrow CL. The pressing member 12 faces the back side of the polishing tape 2. When the movable shaft 16 elevates the pressing member 12 in the pressing direction indicated by the arrow CL, the pressing member 12 comes into contact with the back side of the polishing tape 2. The pressing member 12 presses a polishing surface of the polishing tape 2 against the back surface of the wafer W to polish the back surface of the wafer W with the polishing tape 2. During polishing of the wafer W, the back side of the polishing tape 2 is supported by the pressing member 12. The back side of the polishing tape 2 is a surface opposite to the polishing surface having abrasive grains. During polishing of the wafer W, the polishing tape 2 is advanced in its longitudinal direction at a predetermined speed in an advancing direction indicated by an arrow Z in FIG. 1.

In this specification, unless otherwise particularly described, the longitudinal direction of the polishing tape 2 and the advancing direction of the polishing tape 2 refer to a longitudinal direction of the polishing tape 2 and an advancing direction of the polishing tape 2 on the pressing member 12 of the polishing head 10 that presses the polishing tape 2 against the wafer W.

In this embodiment, the movable shaft 16 is configured as a ball spline shaft. A ball spline nut 32 is disposed in the housing 18, and the movable shaft 16 is supported by the ball spline nut 32 so as to be movable in the axial direction of the movable shaft 16. In one embodiment, the movable shaft 16 may be movably supported by an inner surface of the housing 18.

The housing 18 includes a housing body 18A having a space formed therein for accommodating the movable shaft 16, and a lid 18B that closes the space. The lid 18B is detachably fixed to the housing body 18A by a screw (not shown). The actuator 15 is configured to generate a pressing force for pressing the polishing tape 2 against the wafer W. The actuator 15 includes the movable shaft 16 and the partition membrane 25. The partition membrane 25 is in contact with the end (lower end) of the movable shaft 16, and an edge of the partition membrane 25 is sandwiched between the housing body 18A and the lid 18B. The partition membrane 25 is only in contact with the movable shaft 16, and is not fixed to the movable shaft 16.

The partition membrane 25 is made of a flexible material. Examples of material that can be used to form the partition membrane 25 include chloroprene rubber, fluororubber, and silicone rubber. The pressure chamber 20 is coupled to a compressed-gas supply line (not shown), so that compressed gas (e.g., compressed air) is supplied from the compressed-gas supply line into the pressure chamber 20.

During polishing of the wafer W, the compressed gas, such as compressed air, is supplied into the pressure chamber 20. The pressure of the compressed gas in the pressure chamber 20 acts on the end (lower end) of the movable shaft 16 through the partition membrane 25, and elevates the movable shaft 16, the pressing-member holder 30, and the pressing member 12. The polishing head 10 may further include a distance sensor configured to measure a movement distance of the movable shaft 16 relative to the housing 18. When polishing of the wafer W is to be terminated, the pressure chamber 20 is opened to the atmosphere, and as a result, the movable shaft 16 and the pressing member 12 are lowered by a weight of the movable shaft 16 and a tension of the polishing tape 2.

A skirt 38 is fixed to the pressing-member holder 30. This skirt 38 extends downward from the pressing-member holder 30 and surrounds an upper part of the housing 18. In this embodiment, the skirt 38 has a cylindrical tube shape, but may have another shape as long as the skirt 38 can surround the upper part of the housing 18. The skirt 38 can prevent liquid, such as pure water used in polishing of the wafer W, from entering the housing 18.

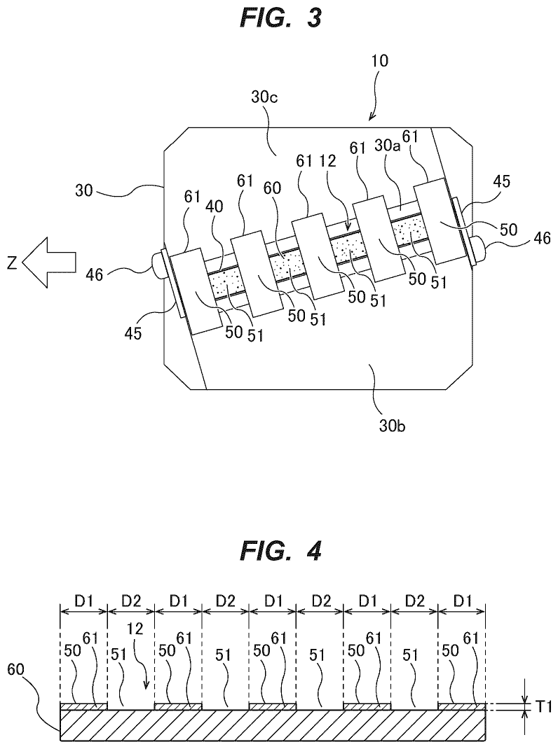

FIG. 3 is a top view showing an embodiment of the pressing member 12, and FIG. 4 is a cross-sectional view of the pressing member 12 shown in FIG. 3. As shown in FIGS. 3 and 4, the pressing member 12 includes a core member 60 having a rod shape, and multiple strip members 61 each covering a part of an upper surface of the core member 60. The core member 60 is fitted in the fitting groove 40 of the pressing-member holder 30 and is detachably held by the pressing-member holder 30. A cross section of the core member 60 has a circular shape. A height of the core member 60 (i.e., a diameter of the cross section of the core member 60) is larger than a depth of the fitting groove 40. Therefore, the upper surface of the core member 60 fitted in the fitting groove 40 is located higher than the pressing surface 30a. In this embodiment, the entire pressing member 12 is disposed obliquely with respect to the advancing direction Z of the polishing tape 2 when viewed from above the polishing head 10. The core member 60 extends linearly and obliquely with respect to the advancing direction Z of the polishing tape 2 when viewed from above the polishing head 10.

The multiple strip members 61 are tapes each having an adhesive surface. In this embodiment, the pressing member 12 includes five strip members 61. The five strip members 61 are arranged along a longitudinal direction of the core member 60 and are arranged along the advancing direction Z of the polishing tape 2. More specifically, the five strip members 61 are arranged obliquely with respect to the advancing direction Z of the polishing tape 2 when viewed from above the polishing head 10. In this specification, arrangement along the advancing direction Z of the polishing tape 2 includes arrangement in a direction parallel to the advancing direction Z of the polishing tape 2 and arrangement obliquely with respect to the advancing direction Z of the polishing tape 2.

In this embodiment, the five strip members 61 are arranged at equal intervals. Each of the multiple strip members 61 is arranged across the core member 60. In this embodiment, each of the multiple strip members 61 extends along a direction perpendicular to the longitudinal direction of the core member 60. The multiple strip members 61 are attached to the core member 60 and the pressing-member holder 30 so as to cover a part of the upper surface of the core member 60. More specifically, as shown in FIG. 2, each of the multiple strip members 61 is attached so as to cover a part of the core member 60 along a curved surface constituting the upper surface of the core member 60. Both sides of each of the strip members 61 are attached to the pressing surface 30a and the slope surfaces 30b and 30c of the pressing-member holder 30. In one embodiment, both sides of each of the strip members 61 may be attached only to the pressing surface 30a of the pressing-member holder 30, and may not be attached to the slope surfaces 30b and 30c. In another embodiment, each of the strip members 61 may be attached only to the upper surface of the core member 60, and may not be attached to the pressing-member holder 30.

With such a configuration, the pressing member 12 of this embodiment has multiple protrusions 50 constituted by the multiple strip members 61 located on the core member 60. The multiple protrusions 50 are arranged along the longitudinal direction of the pressing member 12 and are arranged along the advancing direction Z of the polishing tape 2. More specifically, the multiple protrusions 50 are arranged obliquely with respect to the advancing direction Z of the polishing tape 2 when viewed from above the polishing head 10. As shown in FIG. 4, the multiple protrusions 50 protrude upward from the upper surface of the core member 60 by a thickness T1 of the multiple strip members 61. The pressing member 12 has multiple (four in this embodiment) recesses 51 between the multiple protrusions 50. The multiple recesses 51 are constituted by portions of the upper surface of the core member 60 that are not covered by the strip members 61.

As shown in FIG. 4, in this embodiment, the multiple protrusions 50 have the same size. Specifically, widths D1 of the multiple protrusions 50 are the same. In this embodiment, the multiple protrusions 50 are arranged at equal intervals, and widths D2 of the multiple recesses 51 are the same. Furthermore, in this embodiment, the width D1 of each of the multiple protrusions 50 and the width D2 of each of the multiple recesses 51 are the same. In this embodiment, the width D1 of each of the multiple protrusions 50 corresponds to a width of each of the multiple strip members 61, and the width D2 of each of the multiple recesses 51 corresponds to a distance between adjacent strip members 61.

The core member 60 is made of an elastic material. Therefore, the pressing member 12 has elasticity as a whole. Examples of material that can be used to form the core member 60 include rubber, such as fluororubber, silicone rubber, and ethylene propylene diene rubber. An example of each of the strip members 61 is a tape whose surface is covered with fluororesin (e.g., polytetrafluoroethylene, etc.). However, the core member 60 and the strip members 61 are not limited to this embodiment, and may have other shapes or may be made of other materials. For example, the core member 60 may have a curved shape instead of the shape that extends linearly. In another example, the core member 60 is made of an annular member (e.g., an O-ring), and may be hung on hooks provided on side surfaces of the pressing-member holder 30 so that the core member 60 is supported by the pressing-member holder 30 with the core member 60 elastically deformed.

The polishing head 10 of this embodiment includes two pressing-member stoppers 45 arranged on both ends of the pressing member 12. These pressing-member stoppers 45 are detachably fixed to the pressing-member holder 30 by screws 46. The pressing-member stoppers 45 are made of a hard material, such as resin or metal. The pressing-member stoppers 45 have a function of positioning the pressing member 12 in the longitudinal direction of the pressing member 12.

As shown in FIG. 1, during polishing of the wafer W, the polishing tape 2 is advanced at the predetermined speed in the longitudinal direction of the polishing tape 2 as indicated by the arrow Z. When the wafer W is polished, the pressing member 12 presses the polishing tape 2 against the wafer W from its back side. Since the longitudinal directions of the entire pressing member 12 and the core member 60 are arranged obliquely with respect to the advancing direction Z of the polishing tape 2 when viewed from above the polishing head 10, an unused polishing tape 2 can be brought into contact with the wafer W even at a downstream side of the advancing direction Z of the polishing tape 2. As a result, the polishing rate can be prevented from decreasing due to the use of the polishing tape 2 deteriorated by the polishing of the wafer W. In one embodiment, the longitudinal direction of the entire pressing member 12 and the core member 60 may be parallel to the advancing direction Z of the polishing tape 2.

According to this embodiment, the multiple protrusions 50 of the pressing member 12 are arranged along the longitudinal direction of the pressing member 12 and are arranged along the advancing direction Z of the polishing tape 2, so that the pressing force of the polishing head 10 against the polishing tape 2 is distributed to the multiple protrusions 50. Therefore, the pressing force of the pressing member 12 against the polishing tape 2 is not biased, and as a result, the polishing tape 2 can be pressed against the wafer W uniformly.

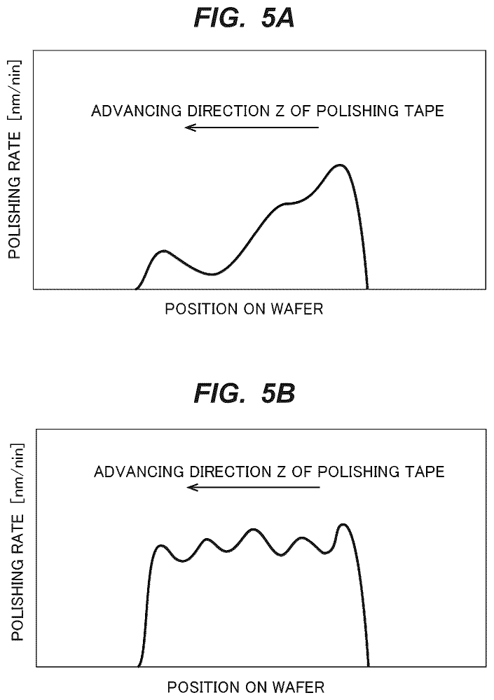

FIG. 5A is a diagram showing an example of a polishing profile when a polishing head 10 including a conventional pressing member that does not have the multiple protrusions 50 is used, and FIG. 5B is a diagram showing an example of a polishing profile when the polishing head 10 including the pressing member 12 having the multiple protrusions 50 is used. In polishing conditions under which the polishing profiles shown in FIG. 5A and FIG. 5B have been obtained, the pressing forces applied to the pressing member 12 by the actuator 15 are the same.

As shown in FIG. 5A, in a polishing region where the polishing tape 2 on the pressing member 12 contacts (hereinafter, simply referred to as a polishing region), a polishing rate of a region located at an upstream side in the advancing direction Z of the polishing tape 2 is higher than a polishing rate of a region located at a downstream side in the advancing direction Z of the polishing tape 2. In contrast, in the polishing profile shown in FIG. 5B, a polishing rate is approximately uniform in the entire polishing region. In this way, the multiple protrusions 50 arranged along the longitudinal direction of the pressing member 12 can achieve a uniform polishing rate. Furthermore, the polishing rate can be improved in the entire polishing region.

As shown in FIG. 5B, the polishing rate in the region corresponding to the multiple protrusions 50 of the pressing member 12 is higher than the polishing rate in the region corresponding to the multiple recesses 51, while the uniformity of the polishing profile is within an allowable range. The height T1 of each of the protrusions 50 of the pressing member 12 (i.e., the thickness of each of the strip members 61), the number of protrusions 50 (i.e., the number of strip members 61), the width D1 of each of the protrusions 50 (i.e., the width of each of the strip members 61), and the width D2 of each of the recesses 51 (i.e., the distance between adjacent strip members 61) are determined in advance based on characteristics of the material that form the pressing member 12 and characteristics of the wafer to be polished, so as to be within the allowable range of a desired polishing profile.

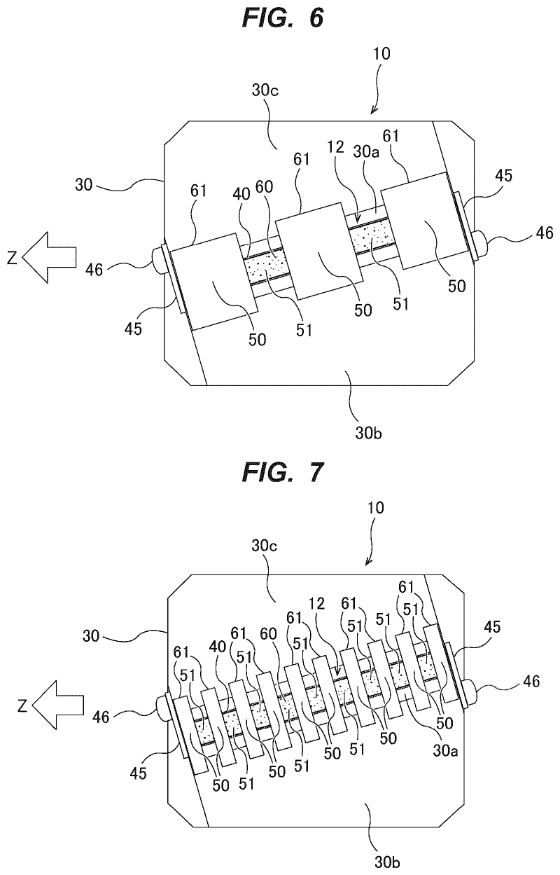

The number of multiple protrusions 50 of the pressing member 12 is not limited to the present embodiment, and may be four or less, or may be six or more. In one embodiment, as shown in FIG. 6, the pressing member 12 may include three strip members 61, and may have three protrusions 50. In another embodiment, as shown in FIG. 7, the pressing member 12 may include ten strip members 61, and may have ten protrusions 50.

In FIGS. 3 and 4, the width D1 of each of the protrusions 50 (i.e., the width of each of the strip members 61) and the width D2 of each of the recesses 51 (i.e., the distance between adjacent strip members 61) are the same, but the width D1 and the width D2 are not limited to this embodiment. In one embodiment, the width D1 of each of the protrusions 50 may be larger than the width D2 of each of the recesses 51, or the width D1 of each of the protrusions 50 may be smaller than the width D2 of each of the recesses 51.

The multiple protrusions 50 in the embodiment shown in FIGS. 3 and 4 have the same size, and the widths D1 of the multiple protrusions 50 (i.e., the widths of the multiple strip members 61) are the same, but the widths D1 of the multiple protrusions 50 (i.e., the widths of the multiple strip members 61) are not limited to this embodiment. The widths D1 of the multiple protrusions 50 may be different. Similarly, the widths D2 of the multiple recesses 51 in the embodiment shown in FIGS. 3 and 4 are the same, but the widths D2 of the multiple recesses 51 are not limited to this embodiment. The widths D2 of the multiple recesses 51 may be different.

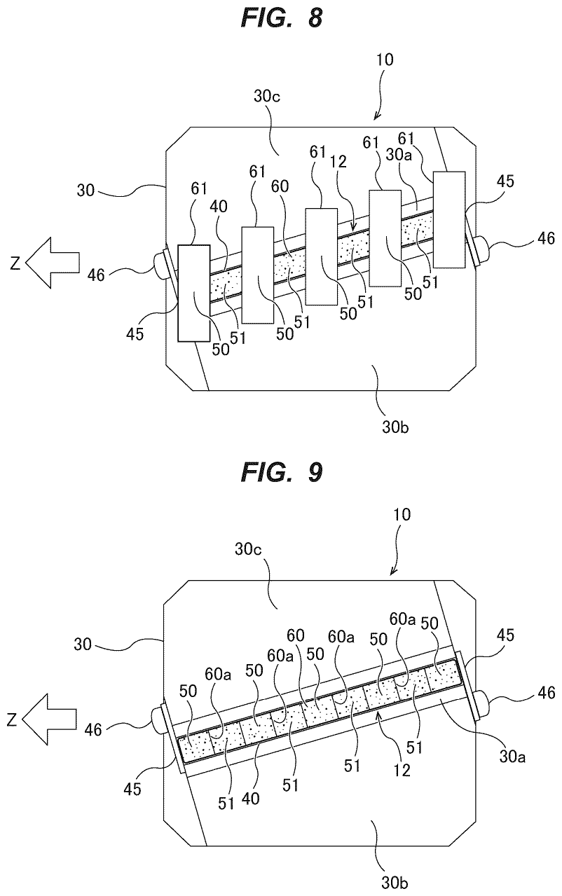

Each of the multiple strip members 61 in the embodiment shown in FIGS. 3 and 4 extends along the direction perpendicular to the longitudinal direction of the core member 60, but the multiple strip members 61 are not limited to this embodiment as long as the multiple protrusions 50 are arranged along the longitudinal direction of the pressing member 12 and are arranged along the advancing direction Z of the polishing tape 2. For example, as shown in FIG. 8, each of the multiple strip members 61 may extend obliquely across the core member 60. In the example shown in FIG. 8, each of the multiple strip members 61 is arranged obliquely with respect to the longitudinal direction of the core member 60, and extends along a direction perpendicular to the advancing direction Z of the polishing tape 2. In this case, the multiple protrusions 50 are also arranged along the longitudinal direction of the pressing member 12 and are also arranged along the advancing direction Z of the polishing tape 2.

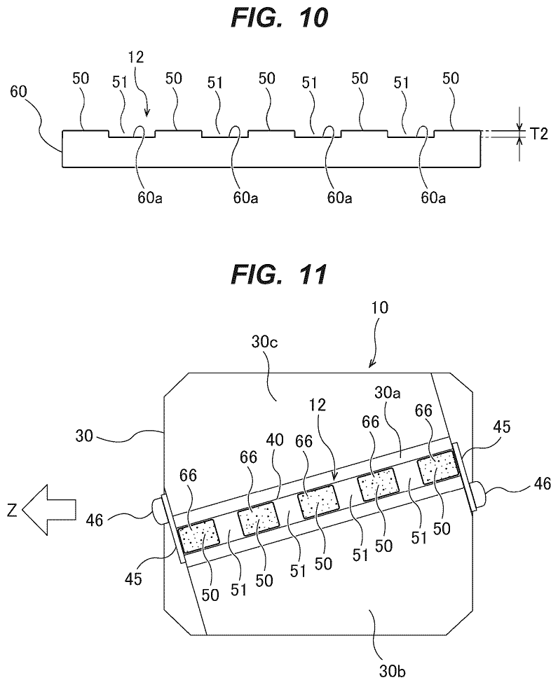

FIG. 9 is a top view showing another embodiment of the pressing member 12, and FIG. 10 is a side view of the pressing member 12 shown in FIG. 9. Details of this embodiment, which will not be particularly described, are the same as those of the embodiments described with reference to FIGS. 1 to 5B, and duplicated descriptions will be omitted. In this embodiment, as shown in FIG. 9 and FIG. 10, the core member 60 of the pressing member 12 has multiple grooves 60a formed in the upper surface of the core member 60. The multiple protrusions 50 are constituted of portions of the upper surface of the core member 60 where the multiple grooves 60a are not formed. The multiple recesses 51 are constituted by the multiple grooves 60a. The pressing member 12 of this embodiment does not have the multiple strip members 61 described above.

The core member 60 is fitted in the fitting groove 40 of the pressing-member holder 30 and is detachably held by the pressing-member holder 30. A height from a lower surface of the core member 60 to bottom surfaces of the multiple grooves 60a is larger than the depth of the fitting groove 40. Therefore, the bottom surfaces of the multiple grooves 60a of the core member 60 fitted in the fitting groove 40 are located higher than the pressing surface 30a. In one embodiment, the height from the lower surface of the core member 60 to the bottom surfaces of the multiple grooves 60a may be smaller than the depth of the fitting groove 40, and the bottom surfaces of the multiple grooves 60a of the core member 60 fitted in the fitting groove 40 may be located lower than the pressing surface 30a.

The multiple (four in this embodiment) grooves 60a are arranged along the longitudinal direction of the core member 60 and are arranged along the advancing direction Z of the polishing tape 2. The multiple (five in this embodiment) protrusions 50 positioned so as to sandwich the multiple recesses 51 are arranged along the longitudinal direction of the pressing member 12, and are arranged along the advancing direction Z of the polishing tape 2. The multiple protrusions 50 protrude upward from the bottom surfaces of the multiple grooves 60a by a depth T2 of the multiple grooves 60a.

In the embodiment shown in FIGS. 9 and 10, the multiple protrusions 50 arranged along the longitudinal direction of the pressing member 12 can also achieve a uniform polishing rate. Furthermore, the polishing rate can be improved in the entire polishing region on the pressing member 12 with which the polishing tape 2 comes into contact.

FIG. 11 is a top view showing still another embodiment of the pressing member 12. Details of this embodiment, which will not be particularly described, are the same as those of the embodiments described with reference to FIGS. 1 to 5B, and duplicated descriptions will be omitted. In this embodiment, as shown in FIG. 11, the pressing member 12 includes multiple core-member pieces 66, and the multiple protrusions 50 of the pressing member 12 are constituted by upper surfaces of the multiple core-member pieces 66. The multiple (five in this embodiment) core-member pieces 66 are fitted in the fitting groove 40 of the pressing-member holder 30 and are detachably held by the pressing-member holder 30. The multiple recesses 51 are formed by gaps between the multiple core-member pieces 66. More specifically, the multiple recesses 51 are formed by portions of the fitting groove 40 in which the multiple core-member pieces 66 are not fitted. A cross section of the core-member piece 66 has a circular shape. A height of the core-member piece 66 (i.e., a diameter in the cross section of the core-member piece 66) is larger than the depth of the fitting groove 40. Therefore, the upper surfaces of the multiple core-member pieces 66 fitted in the fitting grooves 40 are located higher than the pressing surface 30a.

In this embodiment, the entire pressing member 12 is arranged obliquely with respect to the advancing direction Z of the polishing tape 2 when viewed from above the polishing head 10. The multiple (five in this embodiment) core-member pieces 66 are arranged along the longitudinal direction of the fitting groove 40 and are arranged along the advancing direction Z of the polishing tape 2. More specifically, the multiple core-member pieces 66 are arranged obliquely with respect to the advancing direction Z of the polishing tape 2 when viewed from above the polishing head 10. Therefore, the multiple (five in this embodiment) protrusions 50 are arranged along the longitudinal direction of the pressing member 12 and are arranged along the advancing direction Z of the polishing tape 2. More specifically, the multiple protrusions 50 are arranged obliquely with respect to the advancing direction Z of the polishing tape 2 when viewed from above the polishing head 10.

In the embodiment shown in FIG. 11, the multiple protrusions 50 arranged along the longitudinal direction of the pressing member 12 can achieve a uniform polishing rate. Furthermore, the polishing rate can be improved in the entire polishing region polished by the pressing member 12.

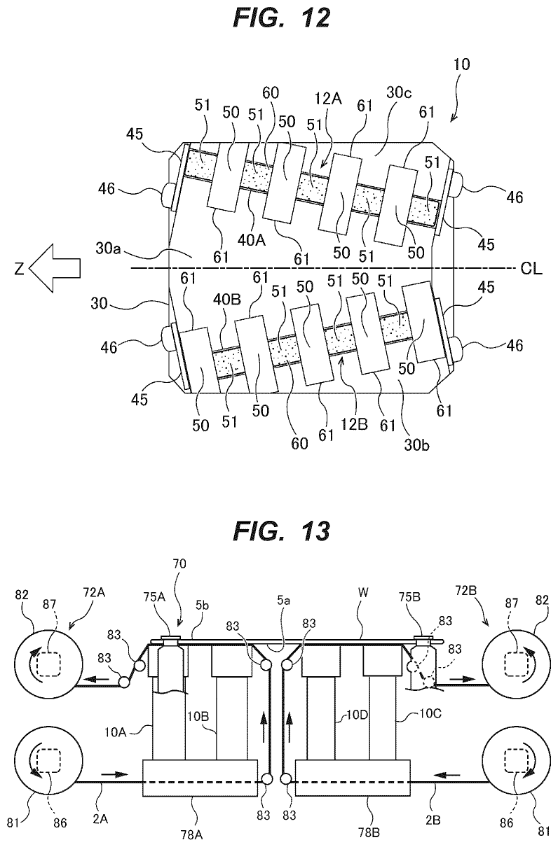

FIG. 12 is a top view showing an embodiment of a polishing head 10 including two pressing members 12A and 12B. The polishing head 10 of this embodiment includes a first pressing member 12A and a second pressing member 12B. Details of this embodiment, which will not be particularly described, are the same as those of the embodiments described with reference to FIGS. 1 to 5B, and duplicated descriptions will be omitted. In this embodiment, the pressing-member holder 30 has a first fitting groove 40A and a second fitting groove 40B formed in the pressing surface 30a of the pressing-member holder 30. At least a part of the first pressing member 12A is fitted in the first fitting groove 40A, and at least a part of the second pressing member 12B is fitted in the second fitting groove 40B. The pressing-member holder 30 has slope surfaces 30b and 30c that are inclined downwardly toward outside from both sides of the pressing surface 30a.

The first pressing member 12A and the second pressing member 12B are arranged at positions away from each other, and are inclined obliquely with respect to the advancing direction Z of the polishing tape 2 when viewed from above the polishing head 10. In this embodiment, the first pressing member 12A and the second pressing member 12B are arranged symmetrically with respect to the advancing direction Z of the polishing tape 2. More specifically, the first pressing member 12A and the second pressing member 12B are arranged symmetrically with respect to a center line CL of the pressing surface 30a extending along the advancing direction Z of the polishing tape 2. In one embodiment, the first pressing member 12A and the second pressing member 12B may not be arranged symmetrically with respect to the advancing direction Z of the polishing tape 2 and the center line CL, as long as the first pressing member 12A and the second pressing member 12B are inclined obliquely with respect to the advancing direction Z of the polishing tape 2.

Each of the first pressing member 12A and the second pressing member 12B includes a core member 60 having a rod shape, and multiple strip members 61 each covering a part of an upper surface of the core member 60. In this embodiment, the first pressing member 12A includes four strip members 61, and the second pressing member 12B includes five strip members 61. The four strip members 61 of the first pressing member 12A are arranged along a longitudinal direction of the core member 60 of the first pressing member 12A and are arranged along the advancing direction Z of the polishing tape 2. More specifically, the four strip members 61 of the first pressing member 12A are arranged obliquely with respect to the advancing direction Z of the polishing tape 2 when viewed from above the polishing head 10.

The five strip members 61 of the second pressing member 12B are arranged along a longitudinal direction of the core member 60 of the second pressing member 12B and are arranged along the advancing direction Z of the polishing tape 2. More specifically, the five strip members 61 of the second pressing member 12B are arranged obliquely with respect to the advancing direction Z of the polishing tape 2 when viewed from above the polishing head 10. The four strip members 61 of the first pressing member 12A and the five strip members 61 of the second pressing member 12B are arranged at different positions in longitudinal directions of the first pressing member 12A and the second pressing member 12B. In other words, the four strip members 61 of the first pressing member 12A and the five strip members 61 of the second pressing member 12B are in a staggered arrangement in the longitudinal directions of the first pressing member 12A and the second pressing member 12B.

With such a configuration, the first pressing member 12A and the second pressing member 12B of this embodiment have multiple protrusions 50 constituted by the multiple strip members 61 located on the core members 60. The multiple protrusions 50 of the first pressing member 12A are arranged along the longitudinal direction of the first pressing member 12A and are arranged along the advancing direction Z of the polishing tape 2. More specifically, the multiple protrusions 50 of the first pressing member 12A are arranged obliquely with respect to the advancing direction Z of the polishing tape 2 when viewed from above the polishing head 10.

The multiple protrusions 50 of the second pressing member 12B are arranged along the longitudinal direction of the second pressing member 12B and are arranged along the advancing direction Z of the polishing tape 2. More specifically, the multiple protrusions 50 of the second pressing member 12B are arranged obliquely with respect to the advancing direction Z of the polishing tape 2 when viewed from above the polishing head 10. The multiple protrusions 50 of the first pressing member 12A and the multiple protrusions 50 of the second pressing member 12B are arranged at different positions in the longitudinal directions of the first pressing member 12A and the second pressing member 12B. In other words, the multiple protrusions 50 of the first pressing member 12A and the multiple protrusions 50 of the second pressing member 12B are in a staggered arrangement in the longitudinal directions of the first pressing member 12A and the second pressing member 12B.

According to this embodiment, the polishing head 10 has the two pressing members 12A and 12B, so that a contact area of the polishing tape 2 with the wafer W can be increased. As a result, a polishing rate of a polishing region corresponding to one polishing head 10 can be increased. Furthermore, the multiple protrusions 50 of the first pressing member 12A and the multiple protrusions 50 of the second pressing member 12B are arranged at the different positions in the longitudinal directions of the first pressing member 12A and the second pressing member 12B, so that a uniform polishing rate can be achieved in the entire polishing region. Each of the modifications described with reference to FIGS. 6 to 11 can also be applied to this embodiment shown in FIG. 12.

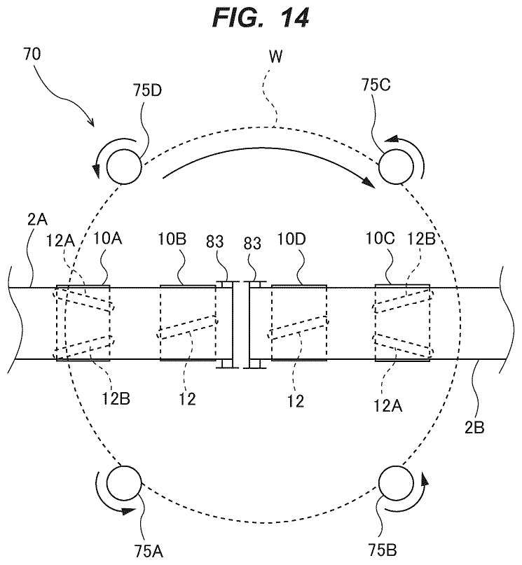

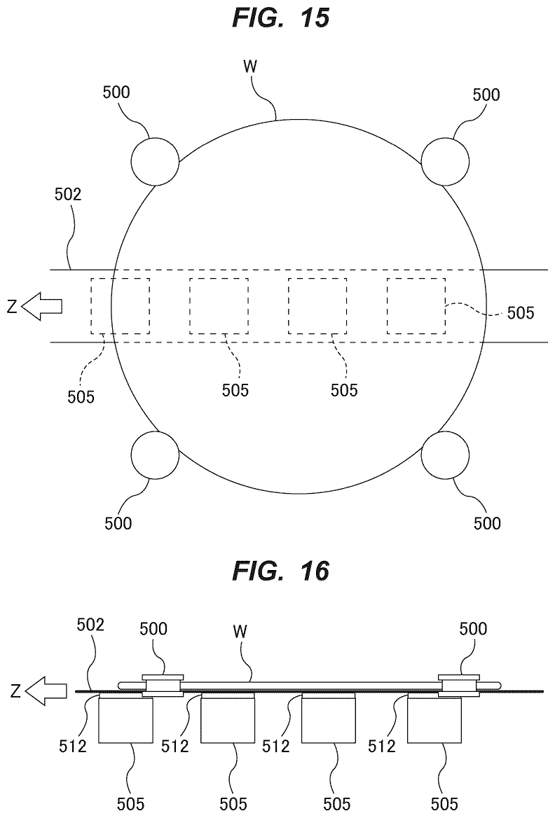

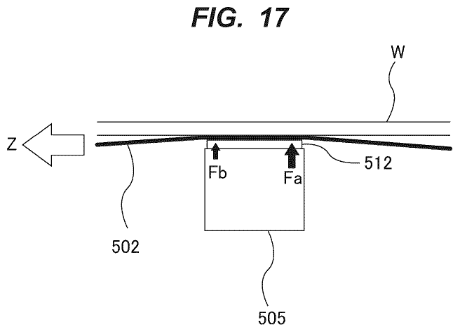

FIG. 13 is a side view showing an embodiment of a polishing apparatus, and FIG. 14 is a top view of the polishing apparatus shown in FIG. 13. The polishing apparatus shown in FIG. 13 and FIG, 14 includes a substrate holder 70 configured to hold and rotate the wafer W, multiple polishing heads 10A to 10D configured to bring polishing tapes 2A and 2B into contact with a first surface 5a of the wafer W held by the substrate holder 70 to polish the first surface 5a of the wafer W, a polishing-tape feeding mechanism 72A configured to feed the polishing tape 2A to the polishing heads 10A and 10B and collect the polishing tape 2 from the polishing heads 10A and 10B, and a polishing-tape feeding mechanism 72B configured to feed the polishing tape 2B to the polishing heads 10C and 10D and collect the polishing tape 2B from the polishing heads 10C and 10D. The polishing tapes 2A and 2B have the same configuration.

The polishing heads 10A and 10C have the same configuration as the polishing head 10 described with reference to FIG. 12, and the polishing heads 10B and 10D have the same configuration as the polishing head 10 described with reference to FIG. 3 and FIG. 4. However, the configurations of the polishing heads 10A to 10D are not limited to this embodiment as long as at least one of the polishing heads 10A to 10D has the configuration of any of the polishing heads of the above-described embodiments. In one embodiment, the polishing heads 10A and 10C have the same configuration as the polishing head 10 described with reference to FIG. 12, the polishing head 10B has the same configuration as the polishing head 10 described with reference to FIG. 3 and FIG. 4, and the polishing head 10D may be a polishing head that does not have the multiple protrusions 50 on the pressing member.

In this embodiment, the first surface 5a of the wafer W is a back surface of the wafer W on which no device is formed or on device is not to be formed, i.e., a non-device surface. A second surface 5b of the wafer W, which is opposite to the first surface 5a, is a surface on which devices are formed or devices are to be formed, i.e., a device surface. In this embodiment, the wafer W is horizontally supported by the substrate holder 70 with the first surface 5a facing downward.

The substrate holder 70 includes multiple rollers 75A, 75B, 75C, and 75D which can contact a periphery of the wafer W, and a roller rotating device (not shown) configured to rotate the rollers 75A to 75D at the same speed. In this embodiment, the four rollers 75A to 75D are provided, while three or five or more rollers may be provided.

The polishing heads 10A and 10B are supported by a supporting member 78A, and the polishing heads 10C and 10D are supported by a supporting member 78B. The polishing heads 10A to 10D are disposed at a lower side of the wafer W held by the substrate holder 70. These polishing heads 10A to 10D are aligned in a diameter direction of the wafer W. In this embodiment, four polishing heads 10A to 10D are provided, while the number of polishing heads is not limited to this embodiment. In one embodiment, a single polishing head may be provided.

As described above, the multiple protrusions 50 of the first pressing member 12A of each of the polishing heads 10A and 10C are arranged along the longitudinal direction of the first pressing member 12A and are arranged along the advancing direction Z of the polishing tape 2. The multiple protrusions 50 of the second pressing member 12B of each of the polishing heads 10A and 10C are arranged along the longitudinal direction of the second pressing member 12B and are arranged along the advancing direction Z of the polishing tape 2. The multiple protrusions 50 of the pressing members 12 of each of the polishing heads 10B and 10D are arranged along the longitudinal direction of the pressing member 12 and are arranged along the advancing direction Z of the polishing tape 2.

Since the polishing-tape feeding mechanisms 72A and 72B have the same configuration, the polishing-tape feeding mechanism 72A will be described below. The polishing-tape feeding mechanism 72A includes a tape feeding reel 81 to which one end of the polishing tape 2A is coupled, a tape take-up reel 82 to which the other end of the polishing tape 2A is coupled, and a plurality of guide rollers 83 configured to guide an advancing direction of the polishing tape 2A. The tape feeding reel 81 and the tape take-up reel 82 are coupled to reel motors 86 and 87, respectively.

The polishing tape 2A is advanced from the tape feeding reel 81 to the tape take-up reel 82 via the polishing heads 10A and 10B when the tape take-up reel 82 is rotated in a direction indicated by an arrow in FIG. 13. The polishing tape 2A is fed over the polishing heads 10A and 10B such that a polishing surface of the polishing tape 2A faces the first surface 5a of the wafer W. The reel motor 86 can apply tension to the polishing tape 2A by applying a predetermined torque to the tape feeding reel 81. The reel motor 87 is controlled so as to advance the polishing tape 2A at a constant speed. An advancing speed of the polishing tape 2A can be changed by changing a rotation speed of the tape take-up reel 82.

In one embodiment, the polishing apparatus may include a tape advancing device configured to feed the polishing tape 2A in the longitudinal direction thereof in addition to the tape feeding reel 81, the tape take-up reel 82, and the reel motors 86 and 87. Furthermore, in another embodiment, positions of the tape feeding reel 81 and the tape take-up reel 82 may be switched.

The wafer W is polished as follows. The wafer W is rotated by the rotating multiple rollers 75A to 75D while the periphery of the wafer W is held by these rollers 75A to 75D. The first pressing member 12A and the second pressing member 12B of the polishing heads 10A and 10C and the pressing members 12 of the polishing heads 10B and 10D press the polishing tapes 2A and 2B against the first surface Sa of the wafer W while the polishing-tape feeding mechanisms 72A and 72B feed the polishing tapes 2A and 2B to the polishing heads 10A to 10D, so that the first surface 5a of the wafer W is polished.

In the above-described embodiments, the polishing head 10 is applied to the polishing apparatus that polishes the back surface (i.e., the non-device surface) of the wafer W, but the polishing head 10 of each of the above-described embodiments can be applied to a polishing apparatus that polishes a front surface (i.e., the device surface) of the wafer W.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a polishing head for pressing a polishing tape against a substrate, such as a wafer. The present invention is further applicable to a polishing apparatus for polishing the substrate with such a polishing head.

### REFERENCE SIGNS LIST

2, 2A, 2B polishing tape
5a first surface
5b second surface
10, 10A to 10D polishing head
12 pressing member
12A first pressing member
12B second pressing member
15 actuator
16 movable shaft
18 housing
18A housing body
18B lid
20 pressure chamber
25 partition membrane (diaphragm)
30 pressing-member holder
30a pressing surface
30b, 30c slope surface
32 ball spline nut
38 skirt
40 fitting groove
40A first fitting groove
40B second fitting groove
45 pressing-member stopper
46 screw
50 protrusion
51 recess
60 core member
60a groove
61 strip member
66 core-member piece
70 substrate holder
72A, 72B polishing-tape feeding mechanism
75A, 75B, 75C, 75D roller
78A, 78B supporting member
81 tape feeding reel
82 tape take-up reel
83 guide roller
86,87 reel motor
W wafer

1. A polishing head for polishing a substrate, comprising:
a pressing member configured to press a polishing tape against a substrate; and
an actuator coupled to the pressing member and configured to apply a pressing force to the pressing member,
wherein the pressing member has multiple protrusions, and
the multiple protrusions are arranged along a longitudinal direction of the pressing member and are arranged along an advancing direction of the polishing tape.

2. The polishing head according to claim 1, wherein the multiple protrusions are arranged obliquely with respect to the advancing direction of the polishing tape.

3. The polishing head according to claim 1, wherein the multiple protrusions are arranged at equal intervals.

4. The polishing head according to claim 1, wherein
the pressing member includes a first pressing member and a second pressing member arranged symmetrically with respect to the advancing direction of the polishing tape,
the multiple protrusions include multiple protrusions of the first pressing member and multiple protrusions of the second pressing member, and
the multiple protrusions of the first pressing member and the multiple protrusions of the second pressing member are arranged at different positions in longitudinal directions of the first pressing member and the second pressing member.

5. A polishing apparatus comprising:
a substrate holder configured to support the substrate; and
the polishing head according to claim 1 for polishing the substrate.
